(19) United States
(12) Patent Application Publication
(10) Pub. No.: US 2024/0329107 A1
(43) Pub. Date: Oct. 3, 2024

(54) CAPACITANCE MEASUREMENT DEVICE

(71) Applicant: LAPIS Technology Co., Ltd., Yokohama-shi (JP)

(72) Inventor: Koki NAKANISHI, Yokohama-shi (JP)

(73) Assignee: LAPIS Technology Co., Ltd., Yokohama-shi (JP)

(21) Appl. No.: 18/615,544

(22) Filed: Mar. 25, 2024

(30) Foreign Application Priority Data
Mar. 28, 2023 (JP) 2023-051547

(51) Int. Cl. G01R 27/26; H03K 17/955

(52) U.S. Cl. CPC G01R 27/2605; H03K 17/955

(57) ABSTRACT

A capacitance measurement device including: a charging switch that connects a measurement node, connected to one-end of a measurement target capacitor, with a power source node that applies a first voltage in an ON state, and disconnects the measurement node from the power source node in an OFF state; a constant current circuit that causes a current of a constant magnitude to flow from the measurement node; a comparator that compares a voltage of the measurement node with a second voltage lower than the first voltage; and a processing unit that performs processing to measure a lapse time from when the charging switch has changed to the OFF state until an output of the comparator flips.

### CROSS-REFERENCE TO RELATED APPLICATION

This application claims priority under 35 USC 119 from Japanese Patent Application No. 2023-051547, filed on Mar. 28, 2023, the disclosure of which is incorporated by reference herein.

### BACKGROUND

### Technical Field

Technology disclosed herein is related to a capacitance measurement device.

### Related Art

The following technology is known as technology related to measurement of capacitance of a capacitor. Japanese Patent Application Laid-Open (JP-A) No. 2019-39771, describes a capacitance measurement device including: a constant current application section that applies a constant current of current value IF to a capacitor; a lapse time measurement section that measures a lapse time from start of constant current application; a voltage measurement section that measures a capacitor voltage when the lapse time has reached a reference time t; and a capacitance computation section that computes a capacitance based on the IF, t, and capacitor voltage.

JP-A No. 2012-37439, describes a capacitance detection circuit that includes: an operational amplifier; a capacitor; and a switch; that performs a sampling action twice under control of the switch, and that, while excluding noise components by taking a difference in the charge voltage of the first time and the second time, converts a capacitance value of a detection target capacitor into a voltage for output. The capacitance detection circuit also includes a first switch and a hold capacitor that are connected in series between an inverting input terminal of the operational amplifier and an output terminal of the operational amplifier.

The following method is an example of a method to measure electrostatic capacitance (electrostatic capacitance) of a capacitor. For example, a measurement target capacitor is charged, and a capacitance Cₚ of the capacitor can be measured from a capacitor voltage drop amount ΔV when charge that had been accumulated in the capacitor is discharged with a constant current I₀ and from a discharge time t. Namely, the capacitance Cₚ is expressed by the following Equation (1).

$${C}_{p} = {I}_{0} \times t / ΔV \qquad Equation ( 1 )$$

The capacitor voltage drop amount ΔV is measured by contacting a probe against the capacitor. However, for example, parasitic capacitance of the probe becomes an issue for capacitors mounted to large scale integrations (LSI) that have minute capacitances in the order of pF. In such case, it is difficult to perform capacitance measurement with high accuracy using the above method, in situations in which the parasitic capacitance of the probe cannot be ignored with respect to the capacitance of the measurement target capacitor.

Although performing a correction to the measurement value to cancel out an amount equivalent to the parasitic capacitance of the probe might be considered, performing such a countermeasure is not practical in a test procedure used for mass production.

### SUMMARY

A first aspect of the present disclosure is a capacitance measurement device including: a charging switch that connects a measurement node, connected to one-end of a measurement target capacitor, with a power source node that applies a first voltage in an ON state, and disconnects the measurement node from the power source node in an OFF state; a constant current circuit that causes a current of a constant magnitude to flow from the measurement node; a comparator that compares a voltage of the measurement node with a second voltage lower than the first voltage; and a processing unit that performs processing to measure a lapse time from when the charging switch has changed to the OFF state until an output of the comparator flips.

A second aspect of the present disclosure is a capacitance measurement device including: a first charging switch that connects a measurement node, connected to one-end of a measurement target capacitor, with a power source node that applies a first voltage in an ON state, and disconnects the measurement node from the power source node in an OFF state; a first constant current circuit that causes a current of a constant magnitude to flow from the first measurement node; a first comparator that compares a voltage of the first measurement node with a second voltage lower than the first voltage; a second charging switch that connects a second measurement node, connected to an other-end of the capacitor, and the power source node in an ON state, and disconnects the second measurement node and the power source node in an OFF state; a second constant current circuit that causes a current of a constant magnitude to flow from the second measurement node; a second comparator that compares a voltage of the second measurement node with the second voltage; and a processing unit that performs processing to respectively measure a lapse time from when the first charging switch has changed to the OFF state until an output of the first comparator flips, and a lapse time from when the second charging switch has changed the OFF state until an output of the second comparator flips.

### BRIEF DESCRIPTION OF THE DRAWINGS

Exemplary embodiments will be described in detail based on the following figures, wherein:

FIG. 1 is a diagram illustrating a configuration of a capacitance measurement device according to an exemplary embodiment of the present disclosure;

FIG. 2 is a flowchart illustrating an operation of the capacitance measurement device according to the exemplary embodiment;

FIG. 3 is a diagram illustrating a configuration of the capacitance measurement device according to another exemplary embodiment; and

FIG. 4 is a flowchart illustrating an operation of a capacitance measurement device according to another exemplary embodiment.

### DETAILED DESCRIPTION

According to the above aspects, a capacitance measurement device of the present disclosure enables the capacitance of a capacitor to be measured without using a probe.

Description follows regarding an example of an exemplary embodiment of the present disclosure, with reference to the drawings. Note that the same reference numerals will be appended in the drawings to the same or equivalent configuration elements and parts, and duplicate explanation thereof will be omitted.

### First Exemplary Embodiment

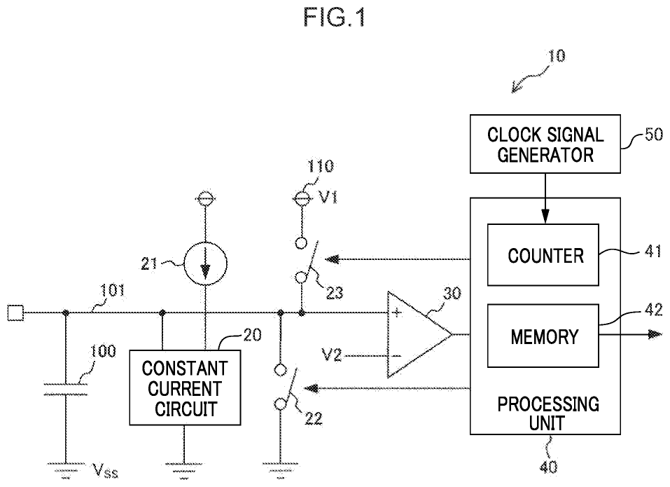

FIG. 1 is a diagram illustrating an example of a configuration of a capacitance measurement device 10 according to a first exemplary embodiment of the present disclosure. The capacitance measurement device 10 is an integrated circuit provided on a semiconductor substrate. The capacitance measurement device 10 includes a function to measure a capacitance of a capacitor 100 inbuilt into an integrated circuit. The capacitance measurement device 10 is configured including a constant current circuit 20, a discharging switch 22, a charging switch 23, a comparator 30, a clock signal generator 50, and a processing unit 40. The processing unit 40 is a microcomputer including a counter 41 and a memory 42.

A measurement node 101 for measuring capacitance is configured at a one-end of the capacitor 100. The other-end of the capacitor 100 is connected to a potential Vss. The potential Vₛₛ may be a ground potential. The constant current circuit 20 is a current mirror circuit, and a transistor (omitted in the drawings) that flows a constant current of the same magnitude to a current generate by a current source 21 is connected to the measurement node 101. The constant current circuit 20 causes a current of constant magnitude to flow out from the measurement node.

The charging switch 23 has a one-end connected to a power source node 110 applied with a voltage V1 (>Vₛₛ), and has an other-end connected to the measurement node 101. The measurement node 101 and the power source node 110 become in a connected state, in a case in which the charging switch 23 is in an ON state, and the capacitor 100 is charged to the voltage V1. The measurement node 101 and the power source node 110 become in a non-connected state, in a case in which the charging switch 23 is in an OFF state.

The discharging switch 22 has a one-end connected to the potential Vₛₛ, and has an other-end connected to the measurement node 101. The measurement node 101 and the potential Vₛₛ become in a connected state, in a case in which the discharging switch 22 is in an ON state, and the charge that had been accumulated in the capacitor 100 is discharged.

The comparator 30 compares a level of voltage of the measurement node 101 against a reference voltage V2. The reference voltage V2 is lower than the voltage V1 of the power source node 110 (V1>V2). A non-inverting input terminal of the comparator 30 is connected to the measurement node 101, and the reference voltage V2 is input to the inverting input terminal of the comparator 30. The comparator 30 outputs a high level signal in a case in which the voltage of the measurement node 101 is higher than the reference voltage V2, and outputs a low level signal in a case in which the voltage of the measurement node 101 is lower than the reference voltage V2. The output signal of the comparator 30 is supplied to the processing unit 40.

The processing unit 40 controls ON/OFF of the discharging switch 22 and the charging switch 23. The charging and discharging of the capacitor 100 is accordingly controlled thereby. After charge accumulated in the capacitor 100 has been discharged with the discharging switch 22 in the ON state, the processing unit 40 places the discharging switch 22 in the OFF state, and the capacitor 100 is then charged to voltage V1 with the charging switch 23 placed in the ON state. The processing unit 40 places the charging switch 23 in the OFF state after charging of the capacitor 100 is complete. Charge that has been accumulated in the capacitor 100 is discharged at a constant current by the constant current circuit 20.

The processing unit 40 employs the counter 41 to measure a lapse time from when the charging switch 23 is in the OFF state, until when the output of the comparator 30 flips from high level to low level. Namely, the lapse time is a count value of the counter 41. The counter 41 performs counting of the cycles of the clock signal output from the clock signal generator 50. The count value corresponding to the above lapse time is recorded in the memory 42. The memory 42 is a non-transitory storage medium such as flash memory or the like. The processing unit 40 performs processing to read the count value recorded in the memory 42 according to external requests.

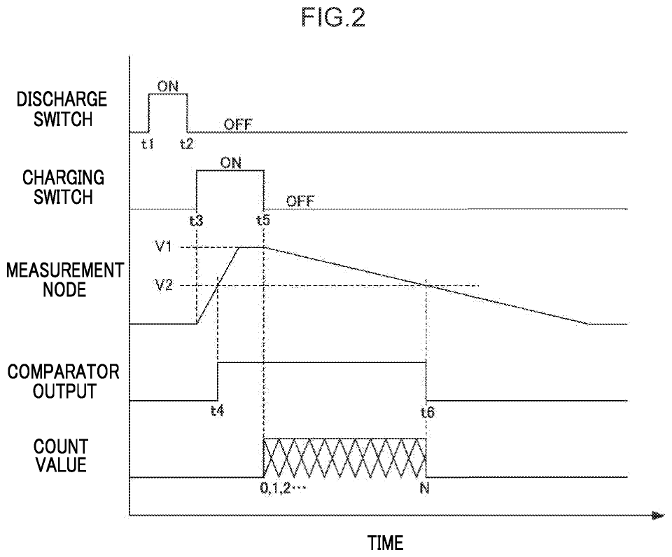

FIG. 2 is a timing chart illustrating an example of operation of the capacitance measurement device 10. FIG. 2 illustrates, in sequence from the top of FIG. 2, timewise transitions in the state of the discharging switch 22, the state of the charging switch 23, the voltage of the measurement node 101, the output signal of the comparator 30, and the count value of the counter 41.

At time t1, the processing unit 40 controls the discharging switch 22 to the ON state. Any charge that has been accumulated in the capacitor 100 is accordingly discharged. At time t2, the processing unit 40 controls the discharging switch 22 to the OFF state. At time t3, the processing unit 40 controls the charging switch 23 to the ON state. The one-end of the capacitor 100 is thereby connected to the power source node 110 via the measurement node 101, and charging of the capacitor 100 is started. The voltage of the measurement node 101 rises toward voltage V1. The output of the comparator 30 transitions to high level when the voltage of the measurement node 101 exceeds the reference voltage V2 at time t4.

At time t5, which is after the voltage of the measurement node 101 has reached voltage V1, the processing unit 40 controls the charging switch 23 to the OFF state. This accordingly stops the charging of the capacitor 100. The counting of counter 41 is started at time t5. The charge that has been accumulated in the capacitor 100 is discharged by the constant current circuit 20. The magnitude of the discharge current is a constant magnitude controlled by the constant current circuit 20. The voltage of the measurement node 101 gradually falls as the charge that has been accumulated in the capacitor 100 is being discharged.

When the voltage of the measurement node 101 falls below the reference voltage V2 at time t6, the output of the comparator 30 flips from high level to low level. The counter 41 stops counting at time t6. The count value of the counter 41 in the period from time t5 to time t6 is recorded in the memory 42.

The processing unit 40 performs processing to read out the count value recorded in the memory 42 according to external requests. The capacitance of the capacitor 100 is computable based on the count value recorded in the memory 42. The capacitance C of the capacitor 100 can be expressed by the following Equation (2), wherein C is the capacitance of the capacitor 100, N is the count value of the counter 41, I₀ is a current the constant current circuit 20 causes to flow out from the measurement node 101 (namely the discharge current of the capacitor 100), and f_{c} is the frequency of the clock signal (namely, the number of counts per unit time).

$$C = {I}_{0} \times N / \{ ( V1 - V2 ) \times {f}_{c} \} \qquad Equation ( 2 )$$

Note that the processing unit 40 may compute the capacitance C of the capacitor 100 by the processing unit 40 executing the above computation.

As stated above, the capacitance measurement device 10 according to the exemplary embodiment of the present disclosure includes: the charging switch 23 that connects the measurement node 101, connected to one-end of the measurement target capacitor 100, and the power source node 110 that applies the voltage V1 in an ON state, and that disconnects the measurement node 101 and the power source node 110 in an OFF state; the constant current circuit 20 causes a current of a constant magnitude to flow from the measurement node 101; the comparator 30 compares the voltage of the measurement node 101 against reference voltage V2 lower than voltage V1; and the processing unit 40 performs processing to measure a lapse time from when the charging switch 23 has changed to the OFF state until the output of the comparator 30 flips. The capacitance measurement device 10 according to the present exemplary embodiment enables a count value that corresponds to the capacitance of the capacitor 100 to be obtained. This count value enables the capacitance of the capacitor 100 to be computed by substituting the count value into Equation (2). Accordingly, the capacitance measurement device 10 according to the present exemplary embodiment may perform measurement of capacitance of the capacitor 100 without using a probe. This accordingly may enable high accuracy capacitance measurement to be performed even for capacitance of capacitors in the pF order, such as those installed in LSI.

### Second Exemplary Embodiment

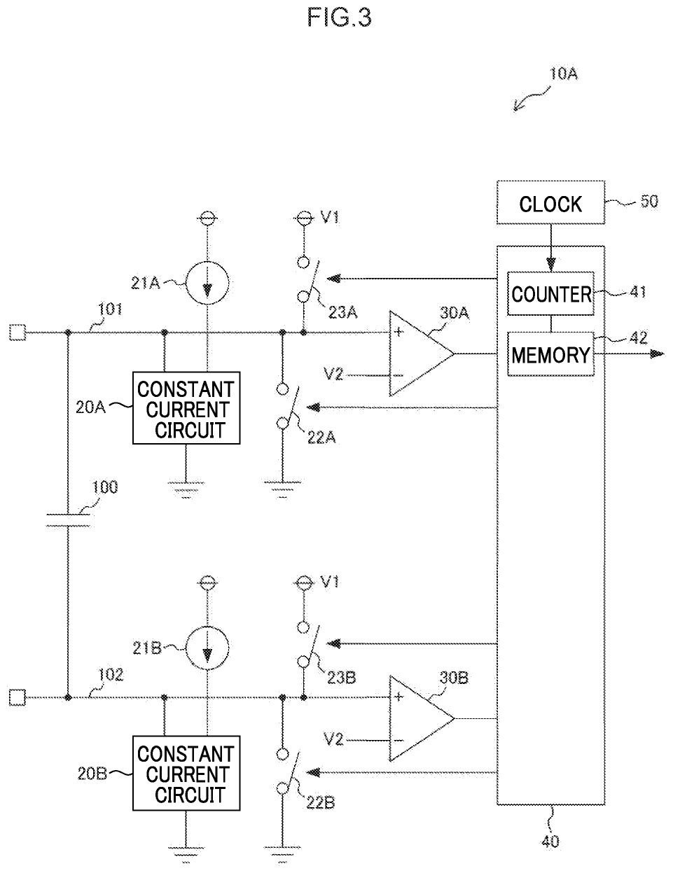

FIG. 3 is a diagram illustrating an example of a configuration of a capacitance measurement device 10A according to a second exemplary embodiment of the present disclosure. The capacitance measurement device 10 according to the first exemplary embodiment is applicable to cases in which one terminal of the measurement target capacitor 100 is connected to the potential Vₛₛ. In contrast thereto, the capacitance measurement device 10A according to the second exemplary embodiment is applicable to cases in which the measurement target capacitor 100 includes differential terminal nodes. The capacitance measurement device 10A according to the second exemplary embodiment is configured including two sets of the circuit set that configured the capacitance measurement device 10 according to the first exemplary embodiment and that included the constant current circuit 20, the current source 21, the discharging switch 22, the charging switch 23, and the comparator 30.

A one-end of the capacitor 100 configure a first measurement node 101, and an other-end of the capacitor 100 configure a second measurement node 102. The capacitance measurement device 10A includes a first circuit set including: a constant current circuit 20A provided to the first measurement node 101; a current source 21A, a discharging switch 22A; a charging switch 23A; and a comparator 30A. The capacitance measurement device 10A also includes a second circuit set including: a constant current circuit 20B provided to the second measurement node 102; a current source 21B; a discharging switch 22B; a charging switch 23B; and a comparator 30B. The connection relationships in the first and second circuit sets for the first and second measurement nodes 101, 102 are similar to those in the circuit set according to the first exemplary embodiment, and so explanation thereof will be omitted.

Output signals of the comparators 30A, 30B are respectively supplied to the processing unit 40. The processing unit 40 controls the ON/OFF states of the discharging switches 22A, 22B and the charging switches 23A, 23B. The discharging of the capacitor 100 is accordingly controlled thereby.

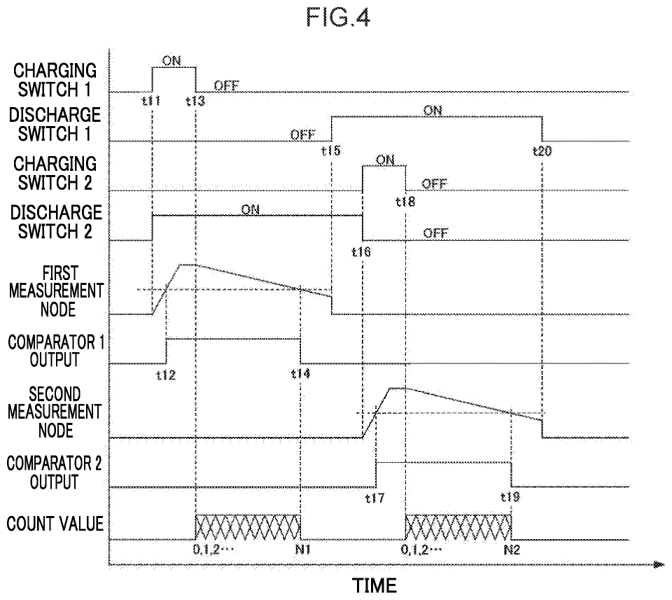

FIG. 4 is a timing chart illustrating an example of operation of the capacitance measurement device 10A. FIG. 4 illustrates, in sequence from the top of FIG. 4, timewise transitions in the state of the charging switch 23A, the state of the discharging switch 22A, the state of the charging switch 23B, the state of the discharging switch 22B, the voltage of the first measurement node 101, the output signal of the comparator 30A, the voltage of the second measurement node 102, the output signal of the comparator 30B, and the count value of the counter 41. Note that, in FIG. 4 the charging switches 23A and 23B are respectively denoted by charging switches 1, 2, the discharging switches 22A, 22B are respectively denoted by discharge switches 1, 2, and the comparators 30A, 30B are respectively denoted by comparators 1, 2.

At time t11, the processing unit 40 respectively controls the charging switch 23A and the discharging switch 22B to ON states. The one-end of the capacitor 100 is thereby connected to the power source node 110 via the first measurement node 101, and the other-end of the capacitor 100 is connected to the potential Vₛₛ via the second measurement node 102. Charging of the capacitor 100 is accordingly started, and the voltage of the first measurement node 101 rises toward voltage V1. The output of the comparator 30A transitions to high level when the voltage of the first measurement node 101 exceeds the reference voltage V2 at time t12.

At time t13, which is after the voltage of the first measurement node 101 has reached V1, the processing unit 40 controls the charging switch 23A to the OFF state. The charging of the capacitor 100 is accordingly stopped. The counting of the counter 41 is started at time t13. The charge accumulated in the capacitor 100 is discharged by the constant current circuit 20A. The magnitude of the discharge current is a constant magnitude controlled by the constant current circuit 20A. The voltage of the first measurement node 101 gradually falls as the charge accumulated in the capacitor 100 is being discharged.

When the voltage of the first measurement node 101 falls below the reference voltage V2 at time t14, the output of the comparator 30A flips from high level to low level. The counter 41 stops counting at time t14. A count value N1 of the counter 41 for the period from time t13 to time t14 is recorded in the memory 42.

At time t15, the processing unit 40 controls the discharging switch 22A to the ON state. The discharging switch 22B is also maintained in the ON state. The charge that has been accumulated in the capacitor 100 is thereby discharged.

At time t16, the processing unit 40 controls the discharging switch 22B to the OFF state, and also controls the charging switch 23B to the ON state. The discharging switch 22A is maintained in the ON state. This means that the one-end of the capacitor 100 is connected to the potential Vₛₛ through the first measurement node 101, and the other-end of the capacitor 100 is connected to power source node 110 via the second measurement node 102. Charging of the capacitor 100 is thereby started, and the voltage of the second measurement node 102 rises toward voltage V1. When the voltage of the second measurement node 102 exceeds the reference voltage V2, at time t17, the output of the comparator 30B transitions to high level.

At time t18, which is after the voltage of the second measurement node 102 has reached V1, the processing unit 40 controls the charging switch 23B to the OFF state. Charging of the capacitor 100 is accordingly stopped. The counting of the counter 41 is started at time t18. The charge that has been accumulated in the capacitor 100 is discharged by the constant current circuit 20B. The magnitude of the discharge current is a constant magnitude controlled by the constant current circuit 20B. The voltage of the second measurement node 102 gradually falls as the charge accumulated in the capacitor 100 is being discharged.

When the voltage of the second measurement node 102 falls below the reference voltage V2, at time t19, the output of the comparator 30B flips from high level to low level. The counting of the counter 41 is stopped at time t19. A count value N2 of the counter 41 during the period from time t18 to time t19 is recorded in the memory 42. The capacitance of the capacitor 100 is computable by substituting the count values N1 and N2 recorded in the memory 42 into Equation (2).

Similarly to the capacitance measurement device 10 according to the first exemplary embodiment, the capacitance measurement device 10A according to the present exemplary embodiment is also able to perform measurement of capacitance of the capacitor 100 without using a probe. Moreover, the capacitance measurement device 10A according to the present exemplary embodiment is able to measure two capacitances (differential capacitances) having mutually different charging directions for a single capacitor 100. Note that although the case described above is one in which both count values N1 and N2 are acquired, one of these may be acquired alone. Moreover, the first circuit set provided to the first measurement node 101 and the second circuit set provided to the second measurement node 102 may respectively have voltages V1, reference voltages V2, and constant currents I₀ that are the same as each other, or are different from each other.

In relation to the above first and second exemplary embodiments, the following supplements are also disclosed.

### Supplement 1

A capacitance measurement device including:
a charging switch that connects a measurement node, connected to one-end of a measurement target capacitor, with a power source node that applies a first voltage in an ON state, and disconnects the measurement node from the power source node in an OFF state;
a constant current circuit that causes a current of a constant magnitude to flow from the measurement node;
a comparator that compares a voltage of the measurement node with a second voltage lower than the first voltage; and
a processing unit that performs processing to measure a lapse time from when the charging switch has changed to the OFF state until an output of the comparator flips.

### Supplement 2

The capacitance measurement device of supplement 1, further comprising a discharge switch connected to the measurement node, the discharge switch discharging charges accumulated in the capacitor in an ON state.

### Supplement 3

The capacitance measurement device of supplement 2, wherein the processing unit controls ON/OFF of the charging switch and the discharge switch.

### Supplement 4

The capacitance measurement device of any one of supplement 1 to supplement 3, wherein the lapse time is a count value of a counter from when the charging switch has changed to the OFF state until the output of the comparator flips.

### Supplement 5

The capacitance measurement device of supplement 4, further including a memory that records the count value.

### Supplement 6

The capacitance measurement device of supplement 4 or supplement 5, wherein the processing unit computes the capacitance of the capacitor based on the count value.

### Supplement 7

A capacitance measurement device including:
a first charging switch that connects a measurement node, connected to one-end of a measurement target capacitor, with a power source node that applies a first voltage in an ON state, and disconnects the measurement node from the power source node in an OFF state;
a first constant current circuit that causes a current of a constant magnitude to flow from the first measurement node;
a first comparator that compares a voltage of the first measurement node with a second voltage lower than the first voltage;
a second charging switch that connects a second measurement node, connected to an other-end of the capacitor, and the power source node in an ON state, and disconnects the second measurement node and the power source node in an OFF state;
a second constant current circuit that causes a current of a constant magnitude to flow from the second measurement node;
a second comparator that compares a voltage of the second measurement node with the second voltage; and
a processing unit that performs processing to respectively measure a lapse time from when the first charging switch has changed to the OFF state until an output of the first comparator flips, and a lapse time from when the second charging switch has changed the OFF state until an output of the second comparator flips.

What is claimed is:

1. A capacitance measurement device comprising:
a charging switch that connects a measurement node, connected to one-end of a measurement target capacitor, with a power source node that applies a first voltage in an ON state, and disconnects the measurement node from the power source node in an OFF state;
a constant current circuit that causes a current of a constant magnitude to flow from the measurement node;
a comparator that compares a voltage of the measurement node with a second voltage lower than the first voltage; and
a processing unit that performs processing to measure a lapse time from when the charging switch has changed to the OFF state until an output of the comparator flips.

2. The capacitance measurement device of claim 1, further comprising a discharge switch connected to the measurement node, the discharge switch discharging charges accumulated in the capacitor in an ON state.

3. The capacitance measurement device of claim 2, wherein the processing unit controls ON/OFF of the charging switch and the discharge switch.

4. The capacitance measurement device of claim 1, wherein the lapse time is a count value of a counter from when the charging switch has changed to the OFF state until the output of the comparator flips.

5. The capacitance measurement device of claim 4, further comprising a memory that records the count value.

6. The capacitance measurement device of claim 4, wherein the processing unit computes the capacitance of the capacitor based on the count value.

7. A capacitance measurement device comprising:
a first charging switch that connects a measurement node, connected to one-end of a measurement target capacitor, with a power source node that applies a first voltage in an ON state, and disconnects the measurement node from the power source node in an OFF state;
a first constant current circuit that causes a current of a constant magnitude to flow from the first measurement node;
a first comparator that compares a voltage of the first measurement node with a second voltage lower than the first voltage;
a second charging switch that connects a second measurement node, connected to an other-end of the capacitor, and the power source node in an ON state, and disconnects the second measurement node and the power source node in an OFF state;
a second constant current circuit that causes a current of a constant magnitude to flow from the second measurement node;
a second comparator that compares a voltage of the second measurement node with the second voltage; and
a processing unit that performs processing to respectively measure a lapse time from when the first charging switch has changed to the OFF state until an output of the first comparator flips, and a lapse time from when the second charging switch has changed the OFF state until an output of the second comparator flips.
